(19) United States
(12) Patent Application Publication
(10) Pub. No.: US 2026/0018392 A1
(43) Pub. Date: Jan. 15, 2026

(54) SUBSTRATE PROCESSING APPARATUS

(71) Applicant: Samsung Electronics Co., Ltd., Suwon-si (KR)

(72) Inventors: Kiyoon Kwon, Suwon-si (KR); YONGHEE KIM, Suwon-si (KR); JONG-KYU KIM, Suwon-si (KR); JUNGHYUN CHO, Suwon-si (KR); SANGOH LEE, Suwon-si (KR); YONGWOO KIM, Suwon-si (KR); JIWON KIM, Suwon-si (KR); DONGHYEON NA, Suwon-si (KR); Hyeonggeun Yun, Suwon-si (KR); JINYEONG HONG, Suwon-si (KR)

(21) Appl. No.: 18/991,819

(22) Filed: Dec. 23, 2024

(30) Foreign Application Priority Data
Jul. 10, 2024 (KR) .10-2024-0091159

(51) Int. Cl. H01J 37/32

(52) U.S. Cl. CPC H01J 37/32715; H01J 2237/2007

(57) ABSTRACT

A substrate processing apparatus according to an exemplary embodiment includes a chamber, a source power supply that provides power for exciting plasma in a form in which the power level pulses, a support member that is disposed inside the chamber and supports a substrate, and a bias voltage supply that is connected to the support member and supplies a voltage for bias, and the power level of the output of the source power supply falls at a power fall time, and the voltage level of the output of the bias voltage supply rises from a control voltage level to a reference voltage level at an end time, and the end time is positioned later than the power fall time by a margin time.

### CROSS-REFERENCE TO RELATED APPLICATION

This application claims priority to and the benefit of Korean Patent Application No. 10-2024-0091159 filed in the Korean Intellectual Property Office on Jul. 10, 2024, the entire contents of which are incorporated herein by reference.

### BACKGROUND OF THE INVENTION

### (a) Field of the Invention

The present disclosure relates to a substrate processing apparatus.

### (b) Description of the Related Art

In order to manufacture a semiconductor device, desired patterns are formed on a substrate by performing various processes, such as photolithography, etching, ashing, ion implantation, thin-film deposition, and cleaning, on the substrate. Among them, the etching process is a process of removing selected regions (e.g., heated regions) of a film formed on a substrate, and wet etching and dry etching are used.

For the dry etching of them, an etching apparatus using plasma may be used. In general, in order to create plasma, an electromagnetic field is created in the inner space of a chamber, and the electromagnetic field excites a process gas provided in the chamber to a plasma state.

Plasma may refer to an ionized gas consisting of ions, electrons, radicals, etc. For example, plasma may be created by very high temperatures, strong electric fields, or RF electromagnetic fields. The semiconductor device manufacturing process may use plasma to perform an etching process. The etching process may be performed by colliding ion particles contained in the plasma with the substrate.

### SUMMARY OF THE INVENTION

The present disclosure provides a substrate processing apparatus capable of effectively processing a substrate by adjusting the motion state of ions when the density of plasma changes.

However, objects which the exemplary embodiments of the present invention attempt to achieve are not confined to the above-mentioned object, and may be broadly diversified without departing from the technical spirit and scope of the present invention.

A substrate processing apparatus according to an aspect may include a chamber, a source power supply configured to generate a source power such that a power level of an output of the source power pulses, thereby exciting plasma in the chamber, a support member that is disposed inside the chamber and is configured to support a substrate, and a bias voltage supply that is connected to the support member and is configured to generate a bias voltage. The source power supply is configured such that the power level of the output of the source power supply falls at a power fall time. The bias voltage supply is configured such that a voltage level of an output of the bias voltage supply rises from a control voltage level to a reference voltage level at an end time, and the end time occurs later than the power fall time by a margin time interval.

A substrate processing apparatus according to another aspect may include a chamber, a source power supply configured to generate a source power such that a power level of an output of the source power pulses, thereby exciting plasma in the chamber, a support member that is disposed inside the chamber and is configured to support a substrate, and a bias voltage supply that is connected to the support member and is configured to generate a bias voltage such that a voltage level of an output of the bias voltage supply pulses. The source power supply is configured such that the power level of the power level of the output of the source power supply falls at a power fall time. The bias voltage supply is configured such that the voltage level of the output of the bias voltage supply is changed between a control section and a reference section, and an end time when the voltage level of the output of the bias voltage supply changes from the control section to the reference section occurs later than the power fall time by a margin time interval.

A substrate processing apparatus according to a further aspect may include a chamber, a source power supply configured to generate a source power such that a power level of an output of the source power pulses, thereby exciting plasma in the chamber, a support member that is disposed inside the chamber and is configured to support a substrate, and a bias voltage supply that is connected to the support member and is configured to generate a bias voltage such that a voltage level of an output of the bias voltage pulses. The source power supply is configured such that the power level of the output of the source power supply rises to 1000 W or more at a power rise time, and to fall to 150 W or less at a power fall time. The bias voltage supply is configured such that the voltage level of the output of the bias voltage supply, at an end time, is changed from a control section to a reference section. The end time occurs later than the power fall time by a margin time interval.

According to an embodiment of the invention, a substrate processing apparatus includes a chamber, a source power supply configured to generate a source power to excite plasma in the chamber and configured such that the source power pulses in a first periodic waveform, a support member disposed inside the chamber and configured to support a substrate, and a bias voltage supply connected to the support member and configured to generate a bias voltage and configured such that the bias voltage pulses in a second periodic waveform., the source power supply is configured such that the source power is repeatedly changed from a first power level to a second power level at each of first times. The bias voltage supply is configured to the bias voltage is repeatedly changed from a first voltage level to a second voltage level at each of second times. Each of the second times occurs later than a corresponding one of the first times by a first time interval. An interval between each of the second times and the corresponding one of the first times is less than a period of the first periodic waveform.

According to the exemplary embodiment, it is possible to provide a substrate processing apparatus capable of effectively processing a substrate by adjusting the motion of ions when the density of plasma changes.

### BRIEF DESCRIPTION OF THE DRAWINGS

FIG. 1 is a view illustrating a substrate processing apparatus according to an exemplary embodiment.

FIG. 2 is a view illustrating a power level which a source power supply supplies according to an exemplary embodiment.

FIG. 3 is a view illustrating a power level which the source power supply supplies according to another exemplary embodiment.

FIG. 4 is a view illustrating a power level which the source power supply supplies according to a further exemplary embodiment.

FIG. 5 is a view illustrating a power level which a bias voltage supply supplies according to an exemplary embodiment.

FIG. 6 is a view illustrating a power level which the bias voltage supply supplies according to another exemplary embodiment.

FIG. 6 is a view illustrating a power level which the bias voltage supply supplies according to a further exemplary embodiment.

FIG. 8 is a view illustrating the state where the output of the source power supply and the output of the bias voltage supply change in sync with each other according to an exemplary embodiment.

FIG. 9 is a view illustrating the ion migration state in the section between a start time and a power drop time.

FIG. 10 is a view illustrating the ion migration state in the section between a power drop time and an end time.

FIG. 11 is a view illustrating the ion migration state in the section between an end time and the power rise time of the next cycle.

FIG. 12 is a view illustrating the state where the output of the source power supply and the output of the bias voltage supply change in sync with each other according to another exemplary embodiment.

FIG. 13 is a view illustrating the state where the output of the source power supply and the output of the bias voltage supply change in sync with each other according to a further exemplary embodiment.

FIG. 14 is a view illustrating the state where the output of the source power supply and the output of the bias voltage supply change in sync with each other according to a still further exemplary embodiment.

FIG. 15 is a view illustrating a substrate processing apparatus according to another exemplary embodiment.

FIG. 16 is a view illustrating a substrate processing apparatus according to a further exemplary embodiment.

FIG. 17 is a view illustrating a substrate processing apparatus according to a still further exemplary embodiment.

FIGS. 18 and 19 are flowcharts illustrating a method of manufacturing a semiconductor device according to an embodiment.

### DETAILED DESCRIPTION OF THE EMBODIMENTS

In the following detailed description, only certain exemplary embodiments of the present invention have been shown and described, simply by way of illustration. The present invention can be variously implemented and is not limited to the following exemplary embodiments.

The drawings and description are to be regarded as illustrative in nature and not restrictive. Like reference numerals designate like elements throughout the specification.

In addition, the size and thickness of each configuration shown in the drawings may be arbitrarily shown for understanding and ease of description, but the present invention is not limited thereto. In the drawings, the thickness of layers, films, panels, regions, etc. may be exaggerated for clarity.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Items described in the singular herein may be provided in plural, as can be seen, for example, in the drawings. Thus, the description of a single item that is provided in plural should be understood to be applicable to the remaining plurality of items unless context indicates otherwise.

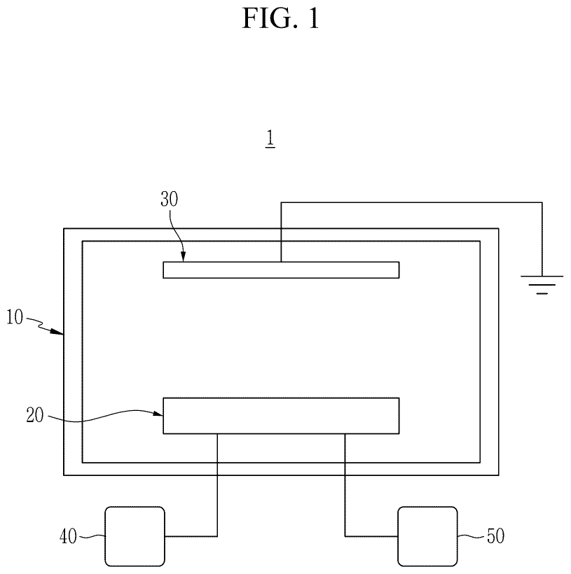

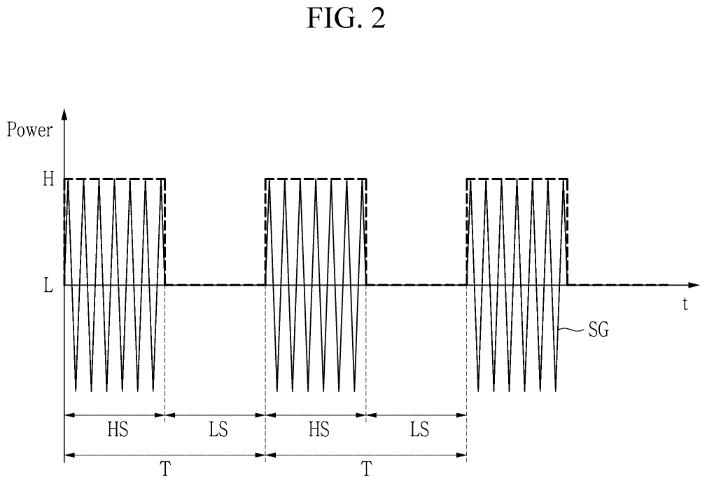

FIG. 1 is a view illustrating a substrate processing apparatus 1 according to an exemplary embodiment.

Referring to FIG. 1, the substrate processing apparatus 1 according to the exemplary embodiment may include a chamber 10, a support member 20, a plasma excitation member 30, a source power supply 40, and a bias voltage supply 50.

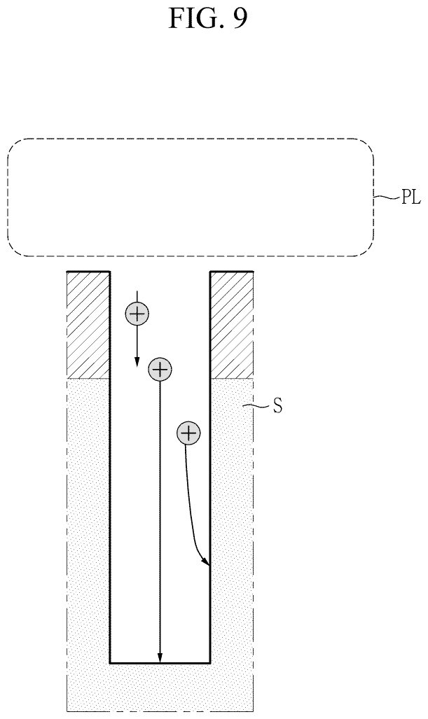

The substrate processing apparatus 1 is utilized to process a substrate (reference symbol “S” in FIG. 9), using plasma (reference symbol “PL” in FIG. 9). As an example, the substrate processing apparatus 1 may be used to perform an etching process or the like using excited plasma PL.

The substrate S may be a wafer or the like for manufacturing semiconductor devices.

The chamber 10 may provide an inner process space where a process for manufacturing the substrate S is performed. The chamber 10 may be provided to seal the inner process space. The chamber 10 may be made of a metal material. As an example, the chamber 10 may be made of an aluminum material, etc. The chamber 10 may be electrically grounded.

The support member 20 may be disposed inside the chamber 10. The support member 20 may be disposed at a lower portion in the process space. The support member 20 is configured to support the substrate S. The support member 20 may adsorb the substrate S, using an electrostatic force. The support member 20 may include a plurality of components. The support member 20 may include an electrostatic chuck and a focus ring. The electrostatic chuck may be disposed at the top of the support member 20. Accordingly, the substrate S may be positioned on the upper surface of the electrostatic chuck. The upper surface of the electrostatic chuck may be made of a dielectric substance. The focus ring may be disposed at the upper outer region of the support member 20. The focus ring may be disposed around the outer periphery of the upper portion of the electrostatic chuck.

Inside the support member 20, a refrigerant flow path may be formed. The refrigerant flow path provides a path through which a refrigerant flows inside the support member 20. As an example, the refrigerant flow path may be formed in a spiral shape. Alternatively, as refrigerant flow paths, ring-shaped flow paths having different radiuses may be disposed concentrically. In this case, the ring-shaped flow paths may be configured to be connected to one another, thereby forming one refrigerant flow path. The refrigerant circulates through the refrigerant flow path, thereby cooling the support member 20. As the support member 20 is cooled, it cools the substrate S positioned on the support member 20.

At least a partial region of the support member 20 may be made of a conductive material. As an example, at least a partial region of the support member 20 may be made of a metal material. Accordingly, the support member 20 may serve as an electrode.

In the support member 20, the region which is made of the conductive material may be positioned below the region which is made of the dielectric material. As an example, the region which is made of the conductive material in the support member 20 may be positioned in the inner region of the support member 20. Accordingly, the region which is made of the conductive material in the support member 20 can be prevented from being exposed to the plasma PL in the course of the process.

The plasma excitation member 30 allows energy for exciting the plasma PL to be applied to the process space (inner process space). The plasma excitation member 30 may be disposed inside the chamber 10. As an example, the plasma excitation member 30 may be manufactured separately from the chamber 10, and be connected to the chamber 10. Alternatively, the plasma excitation member 30 may be provided integrally with the upper structure of the chamber 10. For example, the upper structure of the chamber 10 may serve as the plasma excitation member 30.

The plasma excitation member 30 may be disposed at the upper portion in the process space. The plasma excitation member 30 may be made of a conductive material so as to have a predetermined area. The plasma excitation member 30 may be disposed so as to face the support member 20 in a vertical direction. For example, the plasma excitation member 30 may include a surface having the predetermined area, which faces the support member 20 in the vertical direction.

The source power supply 40 provides power (source power) for excitation of the plasma PL. The source power supply 40 may be electrically connected to the support member 20. The source power supply 40 may be electrically connected to the region which is made of the conductive material in the support member 20. The source power supply 40 may include a high-frequency power source for generating high-frequency power. The source power supply 40 may include or be an RF power source.

The bias voltage supply 50 may be electrically connected to the support member 20, and provides a voltage for bias. The bias voltage supply 50 may be electrically connected to the region which is made of the conductive material in the support member 20. By the voltage which is supplied by the bias voltage supply 50, in the region adjacent to the upper surface of the support member 20, the state of a sheath, the state of concentration of the plasma PL on the substrate S, the state of incidence of ions to the substrate S, and the like may be adjusted. The bias voltage supply 50 may be provided so as to include a voltage source, and outputs a voltage.

In an embodiment of the invention, the bias voltage supply 50 may be configured to control the plasma PL by the voltage (bias voltage) which is supplied by the bias voltage supply 50. For example, in the region adjacent to the upper surface of the support member 20, the bias voltage may be adjusted by the voltage source to control the sheath and the concentration of the plasma PL on the substrate S and to control the incidence of ions to the substrate S.

A process gas introduced into the chamber 10 may be excited into plasma PL by an electric field formed inside the chamber 10. Specifically, the process gas may be excited into plasma PL by a capacitively coupled plasma (CCP) configuration. The capacitively coupled plasma configuration may include an upper electrode and a lower electrode. The upper electrode and the lower electrode may be disposed inside the chamber 10 so as to face each other in the vertical direction.

To at least one of the upper electrode and the lower electrode, high-frequency power may be applied such that an electromagnetic field is formed in the space between the upper electrode and the lower electrode, and the process gas introduced into this space may be excited and changed into the plasma (PL) state. The upper electrode may be the plasma excitation member 30, and the lower electrode may be the support member 20.

The source power supply 40 may be electrically connected to the plasma excitation member 30 and/or the support member 20, and the source power supply 40 may provide source power to the plasma excitation member 30 and/or the support member 20. For example, one of the upper electrode and the lower electrode may be connected to a high-frequency power source (e.g., source power supply 40). As an example, the upper electrode may be grounded, and the lower electrode may be connected to a high-frequency power source. As another example, the lower electrode may be grounded, and the upper electrode may be connected to a high-frequency power source. Alternatively, both of the upper electrode and the lower electrode may be connected to high-frequency power sources. FIG. 1 illustrates the case where the lower electrode is connected to a high-frequency power source.

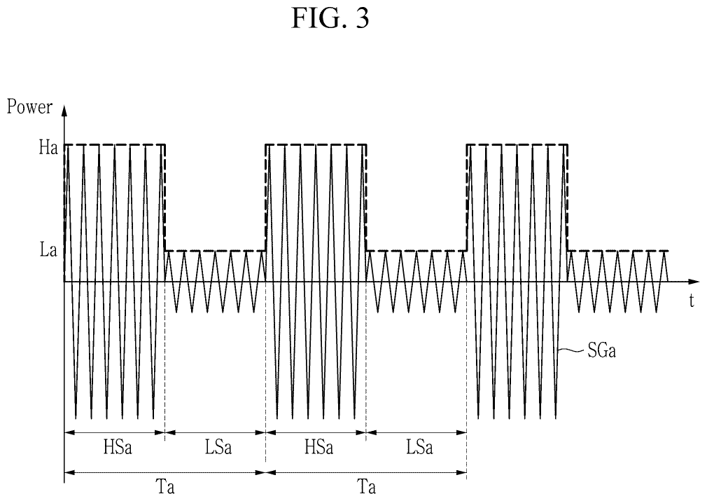

FIG. 2 is a view illustrating the power level which is supplied by the source power supply 40 according to an exemplary embodiment. The horizontal axis represents time and the vertical axis represents power.

Referring to FIG. 2, the power level which is supplied by the source power supply 40 may be pulsed over time. The source power supply 40 may be configured to generate power for exciting plasma in the chamber and to control the power to be pulsed. For example, the source power supply 40 may be configured to supply power in short, rapid bursts or intervals (rather than in a continuous flow). The source power supply 40 may be configured to supply power in a controlled way to regulate or modulate the power. The source power supply 40 may provide power (source power) in a periodic waveform with a predetermined period (which may be referred to as a period T or one period T). The period T may be the length of time it takes for the waveform to complete a full cycle and return to its starting point. The starting point for measuring a predetermined period may be chosen at any location within the waveform, though it is illustrated as being at the vertical axis of the graph in FIG. 2. The source power supply 40 may be controlled by a computer or other controller or hardware device (e.g., a DSP, an FPGA, a CPU, a GPU, a microprocessor, etc.) using computer program code, so that the period and modulation of the power may be controlled by the computer program code. The source power supply 40 may be configured to supply the various power waveforms described herein based on, for example, the control by the controller.

Specifically, the output of the source power supply 40 may include a high-level section HS and a low-level section LS. The low power level L of the low-level section LS may be lower than the high power level H of the high-level section HS. In this disclosure, when describing the source power by using terms like “high,” “low,” “increase,” “decrease,” “fall,” and “rise,” it may be based on the absolute value of the source power. For example, the source power may include a high-level section and a low-level section, each corresponding to the high and low power levels H and L, respectively, and the absolute value of the low power level L of the low-level section LS may be lower than the absolute value of the high power level H of the high-level section HS. The high-level section HS may be a source power-on section, and the low-level section LS may be a source power-off section. For example, the low power level L of the low-level section LS may be 0 W. The high power level H of the high-level section HS may exceed 150 W. The high power level H of the high-level section HS may be equal to or higher than 1000 W.

The high-level section HS and the low-level section LS may become a (one) period T of the output of the source power supply 40. For example, the output of the source power supply 40 may be a repetition of one period T having a preset length. Accordingly, the period T may include the high-level section HS and the low-level section LS. The output of the source power supply 40 may be in a waveform with the high-level section HS and the low-level section LS such that the output of the source power supply 40 may be repeatedly changed by the period T having a predetermined length. The period T may be an interval corresponding to the sum of the high-level section HS and the low-level section LS.

The output of the source power supply 40 may be a waveform of the RF power. The properties of this waveform may affect plasma characteristics. For example, the output of the source power supply 40 may be pulsed RF power, where the RF signal alternates between on and off states (e.g., high and low power levels H and L). This may allow for better control over plasma characteristics and may reduce heat load on materials being processed. In some embodiments, the output of the source power supply 40 may be a sinusoidal AC signal. The power level of the source power supply 40 may correspond to the envelope of the RF signal. For example, as shown in FIG. 2, the output signal SG of the source power supply 40 may have a preset RF. As an example, the frequency of the output signal SG of the source power supply 40 may range from 50 MHz to hundreds of MHz. The waveform of the output signal SG of the source power supply 40 may be a sinusoidal waveform or the like. The power level of the output of the source power supply 40 may be the envelope of the output signal SG having the RF. As an example, the amplitude of the output signal SG of the source power supply 40 may change over time. In this case, the change in amplitude may include a change in amplitude to 0. Accordingly, the power level of the output of the source power supply 40 may be pulsed.

FIG. 3 is a view illustrating a power level which is supplied by the source power supply 40 according to another exemplary embodiment. The horizontal axis represents time and the vertical axis represents power.

Referring to FIG. 3, the power level which is supplied by the source power supply 40 may be pulsed over time. Specifically, the output of the source power supply 40 may include a high-level section HSa and a low-level section LSa. Both the high-level section HSa and the low-level section LSa may be source power-on sections. The low power level La of the low-level section LSa may be lower than the high power level Ha of the high-level section HSa. The low power level La and the high power level Ha may be absolute values. The high power level Ha of the high-level section HSa may exceed 150 W. As an example, the high power level Ha of the high-level section HSa may be equal to or higher than 1000 W. The low power level La of the low-level section LS may exceed 0 W and be equal to or lower than 150 W.

The high-level section HSa and the low-level section LSa may become one period Ta of the output of the source power supply 40. The output of the source power supply 40 may be a repetition of the period Ta having a preset length. Accordingly, the period Ta may include a high-level section HSa and a low-level section LSa.

An output signal SGa of the source power supply 40 may have a preset RF. As an example, the frequency of the output signal SGa of the source power supply 40 may range from 50 MHz (mega-Hertz) to hundreds of MHz. The waveform of the output signal SGa of the source power supply 40 may be a sinusoidal waveform or the like. The power level of the output of the source power supply 40 may be the envelope of the output signal SGs having the RF. As an example, the amplitude of the output signal SGa of the source power supply 40 may change over time. Accordingly, the power level of the output of the source power supply 40 may be pulsed.

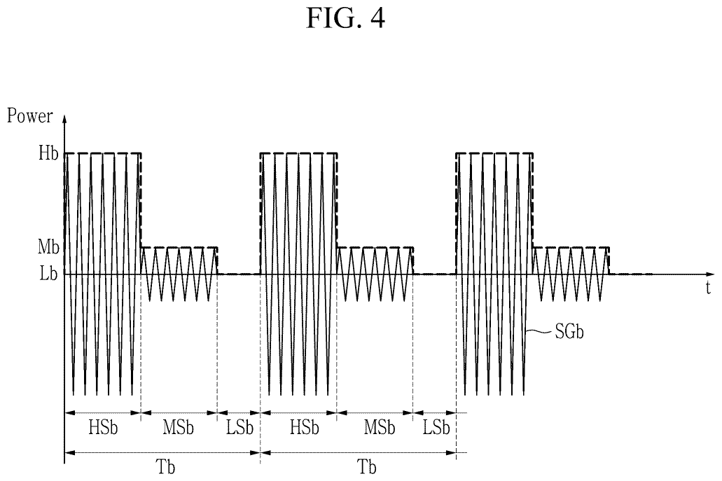

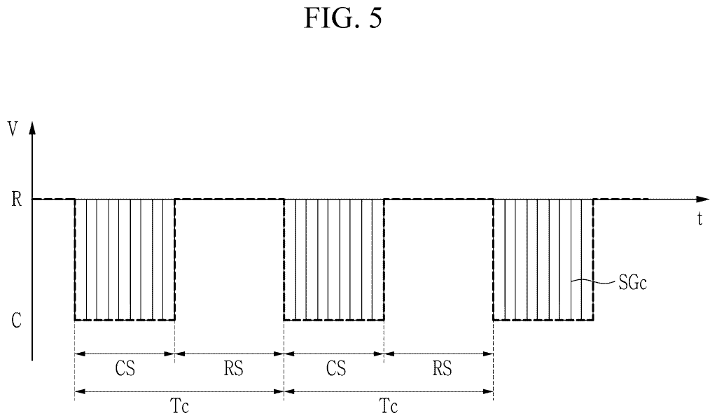

FIG. 4 is a view illustrating a power level which is supplied by the source power supply 40 according to a further exemplary embodiment. The horizontal axis represents time and the vertical axis represents power.

Referring to FIG. 4, the power level which is supplied by the source power supply 40 may be pulsed over time. Specifically, the output of the source power supply 40 may include a high-level section HSb, a middle-level section Mb, and a low-level section LSb. The middle power level Mb of the middle-level section Mb may be lower than the high power level Hb of the high-level section HSb. The low power level Lb of the low-level section LSb may be lower than the high power level Hb of the high-level section HSb and the middle power level Mb of the middle-level section Mb. The low power level Lb, the middle-level section Mb, and the high power level Hb may be absolute values. As an example, both the high-level section HSb and the middle-level section Mb may be source power-on sections. The high power level Hb of the high-level section HSb may exceed 150 W. As an example, the high power level Hb of the high-level section HSb may be equal to or higher than 1000 W. The middle power level Mb of the middle-level section Mb may exceed 150 W. In some embodiments, the middle power level Mb of the middle-level section Mb may exceed 0 W and be equal to or lower than 150 W.

The low-level section LSb may be a source power-off section. Accordingly, the low power level Lb of the low-level section LSb may be 0 W.

The high-level section HSb, the middle-level section Mb, and the low-level section LSb may become one period Tb of the output of the source power supply 40. In other words, the output of the source power supply 40 may be a repetition of the period Tb having a preset length. Accordingly, the period Tb may include a high-level section HSb, a middle-level section Mb, and a low-level section LSb. The output of the source power supply 40 may be in a waveform with high-level section HSb, the middle-level section Mb, and the low-level section LSb such that the output of the source power supply 40 may be repeatedly changed by the period Tb having a preset length.

An output signal SGb of the source power supply 40 may have a preset RF. As an example, the RF of the output signal SGb of the source power supply 40 may range from 50 MHz to hundreds of MHz. The waveform of the output signal SGb of the source power supply 40 may be a sinusoidal waveform or the like. The power level of the output of the source power supply 40 may be the envelope of the output signal SGs having the RF. As an example, the amplitude of the output signal SGb of the source power supply 40 may change over time. Accordingly, the power level of the output of the source power supply 40 may be pulsed. In this case, the change in amplitude may include a change in amplitude to 0. For example, the amplitude of the waveform may be the change of power from the high power level Hb to low power level Lb.

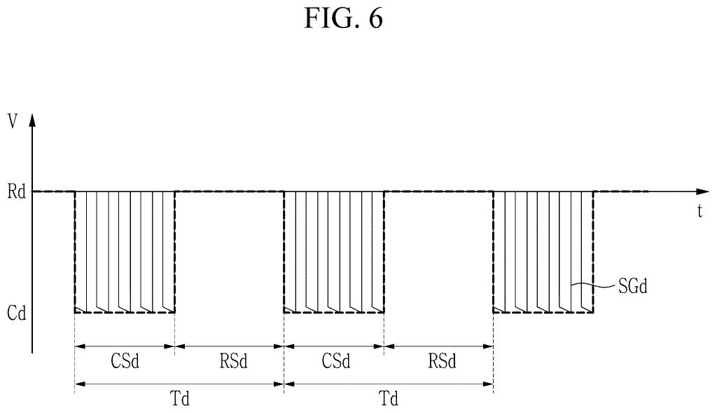

FIG. 5 is a view illustrating the voltage level which is supplied by the bias voltage supply 50 according to an exemplary embodiment. The horizontal axis represents time and the vertical axis represents voltage.

Referring to FIG. 5, the voltage level which is supplied by the bias voltage supply 50 may be pulsed over time to provide the bias voltage in a periodic waveform with a predetermined period. The bias voltage supply 50 may be configured to control a bias voltage to be pulsed such that, for example, the bias voltage supply 50 is configured to deliver the bias voltage in short, rapid bursts or intervals (rather than in a continuous flow) and in a controlled way to regulate or modulate the bias voltage. Specifically, the output of the bias voltage supply 50 may include a control section CS and a reference section RS. The bias voltage supply 50 may output a control voltage level C in the control section CS. The control voltage level C may be provided as a negative value.

The predetermined period (which may be referred to as a period Tc or one period Tc) of the bias voltage may be the length of time it takes for the waveform to complete a full cycle and return to its starting point. For example, the length of the period Tc of the output of the bias voltage supply 50 may be equal to the length of each of the period T, Ta, or Tb of the output of the source power supply 40 shown in FIGS. 2 to 4. The period Tc of the output of the bias voltage supply 50 may include a control section CS and a reference section RS. The section of one period Tc other than the control section CS may become the reference section RS. For example, the control section CS may encompass all of the period Tc that is not included in the reference section RS. The output of the bias voltage supply 50 may change at the boundary between the control section CS and the reference section RS.

The bias voltage supply 50 may output a reference voltage level R in the reference section RS. The output of the bias voltage supply 50 may be at the reference voltage level R before the former end of the control section CS. The output of the bias voltage supply 50 may be at the reference voltage level R after the latter end of the control section CS. The reference voltage level R may have a value larger than that of the control voltage level C. The absolute value of the reference voltage level R may be smaller than the absolute value of the control voltage level C. The reference voltage level R may be 0 V.

An output signal SGc of the bias voltage supply 50 may have a preset bias frequency. As an example, the bias frequency may range from 300 KHz to 600 KHz. The output signal SGc of the bias voltage supply 50 may be a pulse of DC voltage. The waveform of the output signal SGc of the bias voltage supply 50 may be a square waveform or the like. The voltage level of the output of the bias voltage supply 50 may be the envelope of the output signal SGc having the bias frequency. As an example, the amplitude of the output signal SGc of the bias voltage supply 50 may change over time. In this case, the change in amplitude may include a change in amplitude to 0. Accordingly, the voltage level of the output of the bias voltage supply 50 may be pulsed.

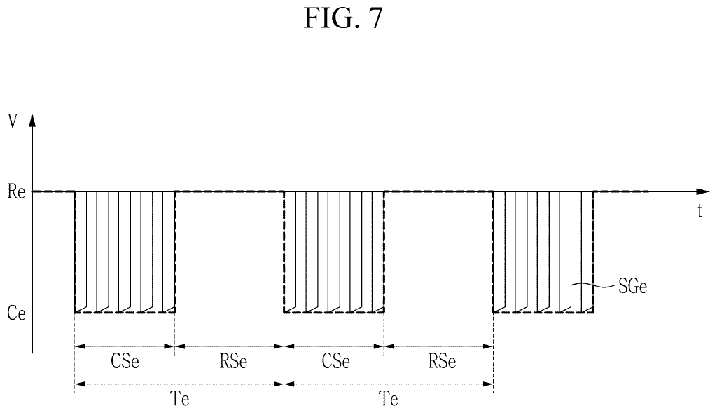

FIG. 6 is a view illustrating the voltage level which is supplied by the bias voltage supply 50 according to another exemplary embodiment. The horizontal axis represents time and the vertical axis represents voltage.

Referring to FIG. 6, the voltage level which is supplied by the bias voltage supply 50 may be pulsed over time. Specifically, the output of the bias voltage supply 50 may include a control section CSd and a reference section RSd. The bias voltage supply 50 may output a voltage having a control voltage level Cd in the control section CS. The control voltage level Cd may be provided as a negative value.

The length of one period Td of the output of the bias voltage supply 50 may be equal to the length of each of the periods T, Ta, or Tb of the output of the source power supply 40 shown in FIGS. 2 to 4. The one period Td of the output of the bias voltage supply 50 may include a control section CSd and a reference section RSd. The section of the period Td other than the control section CSd may become a reference section RSd. The output of the bias voltage supply 50 may change at the boundary between the control section CSd and the reference section RSd.

Similar to the source power supply 40, the bias voltage supply 50 may be controlled by a computer or other controller or hardware device (e.g., a DSP, an FPGA, a CPU, a GPU, a microprocessor, etc.) using computer program code, so that the period and modulation of the bias voltage may be controlled by the computer program code. The bias voltage supply 50 may be configured to supply the various voltage waveforms described herein based on, for example, the control by the controller.

The bias voltage supply 50 may output a reference voltage level Rd in the reference section RSd. The output of the bias voltage supply 50 may be at the reference voltage level Rd before the former end of the control section CSd. The output of the bias voltage supply 50 may be at the reference voltage level Rd after the latter end of the control section CSd. The reference voltage level Rd may have a value larger than that of the control voltage level Cd. The absolute value of the reference voltage level Rd may be smaller than the absolute value of the control voltage level Cd. The reference voltage level Rd may be 0 V.

An output signal SGd of the bias voltage supply 50 may have a preset bias frequency. As an example, the bias frequency may range from 300 KHz to 600 KHz. The waveform of the output signal SGd of the bias voltage supply 50 may be a non-sinusoidal waveform. As an example, the waveform of the output signal SGd of the bias voltage supply 50 may have a slope in an on-duty section. Specifically, the waveform of the output signal SGd of the bias voltage supply 50 may have a slope that slopes downward (i.e., a slope at which the absolute value of the voltage increases) over time, in an on-duty section. The voltage level of the output of the bias voltage supply 50 may be the envelope of the output signal SGd of the bias voltage supply 50 having the bias frequency. As an example, the amplitude of the output signal SGd of the bias voltage supply 50 may change over time. In this case, the change in amplitude may include a change in amplitude to 0. Accordingly, the voltage level of the output of the bias voltage supply 50 may be pulsed.

FIG. 7 is a view illustrating the voltage level which is supplied by the bias voltage supply 50 according to a further exemplary embodiment. The horizontal axis represents time and the vertical axis represents voltage.

Referring to FIG. 7, the voltage level which is supplied by the bias voltage supply 50 may be pulsed over time. Specifically, the output of the bias voltage supply 50 may include a control section CSe and a reference section RSe. The bias voltage supply 50 may output a control voltage level Ce in the control section CSe. The control voltage level Ce may be provided as a negative value.

The length of one period Te of the output of the bias voltage supply 50 may be equal to the length of the period T, Ta, or Tb of the output of the source power supply 40 shown in FIGS. 2 to 4. The period Te of the output of the bias voltage supply 50 may include a control section CSe and a reference section RSe. The section of the period Te other than the control section CSe may become a reference section RSe. The output of the bias voltage supply 50 may change at the boundary between the control section CSe and the reference section RSe.

The bias voltage supply 50 may output a reference voltage level Re in the reference section RSe. The output of the bias voltage supply 50 may be at the reference voltage level Re before the former end of the control section CSe. The output of the bias voltage supply 50 may be at the reference voltage level Re after the latter end of the control section CSe. The reference voltage level Re may have a value larger than that of the control voltage level Ce. The absolute value of the reference voltage level Re may be smaller than the absolute value of the control voltage level Ce. The reference voltage level Re may be 0 V.

An output signal SGe of the bias voltage supply 50 may have a preset bias frequency. As an example, the bias frequency may range from 300 KHz to 600 KHz. The waveform of the output signal SGe of the bias voltage supply 50 may be a non-sinusoidal waveform. As an example, the waveform of the output signal SGe of the bias voltage supply 50 may have a slope in an on-duty section. Specifically, the waveform of the output signal SGe of the bias voltage supply 50 may have a slope that slopes upward (i.e., a slope at which the absolute value of the voltage decreases) over time, in an on-duty section. The voltage level of the output of the bias voltage supply 50 may be the envelope of the output signal SGe having the bias frequency. As an example, the amplitude of the output signal SGe of the bias voltage supply 50 may change over time. In this case, the change in amplitude may include a change in amplitude to 0. Accordingly, the voltage level of the output of the bias voltage supply 50 may be pulsed.

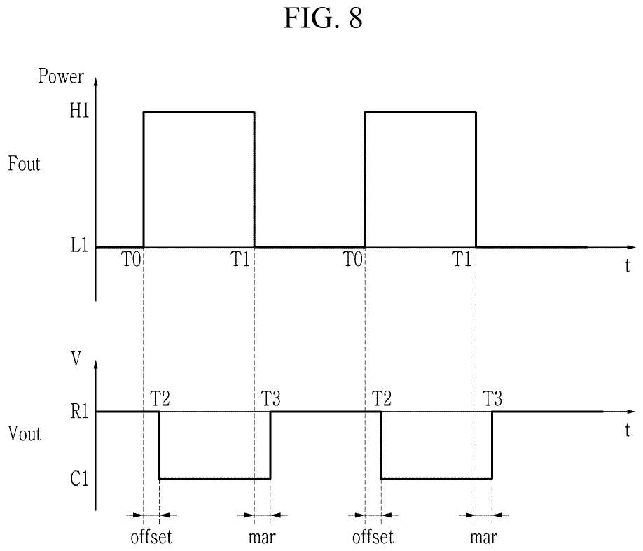

FIG. 8 is a view illustrating the state where the output Fout of the source power supply 40 and the output Vout of the bias voltage supply 50 change in sync with each other according to an exemplary embodiment. For example, in the synchronized variations of the output Fout and the output Vout, the periods of the source power supply 40 and the bias voltage supply 50 may be the same as each other.

The output Fout of the source power supply 40 may be a partial section of the output of the source power supply 40 described with reference to FIG. 2. The output Vout of the bias voltage supply 50 may be a partial section of one of the outputs of the bias voltage supply 50 described with reference to FIGS. 5 to 7.

Referring to FIG. 8, in each of the periods (cycles) of the waveform of the power level, the power level of the output Fout of the source power supply 40 may rise from a corresponding low-level section to a high power level H1 at a corresponding power rise time T0, thereby changing to a corresponding high-level section. For example, in a first period (cycle) after the source power supply 40 starts to supply power, at a power rise time T0, the output Fout of the source power supply 40 may change from 0 W to a high-level section, or may change from a low-level section to the high-level section. Similarly, in a second period after the first period, at a power rise time T0, the output Fout of the source power supply 40 may change from a low-level section to a high-level section.

In each of the periods (cycles) of the waveform of the power level, the power level of the output Fout of the source power supply 40 may fall, at a corresponding power fall time T1, thereby changing to a corresponding low-level section. For example, at each power fall time T1, the output Fout of the source power supply 40 may change from a corresponding high-level section to a corresponding low-level section. Accordingly, at each power fall time T1, the power level of the output Fout of the source power supply 40 may fall from the high power level H1 to a low power level L1.

The high-level section may be an interval between the power rise time TO and the power fall time T1 in each of the periods (cycles).

The voltage level of the output Vout of the bias voltage supply 50 may fall from a reference voltage level R1 to a control voltage level C1 at each start time T2. At each start time T2, the output Vout of the bias voltage supply 50 may change from a corresponding reference section to a corresponding control section. The voltage level of the output Vout of the bias voltage supply 50 may rise from the control voltage level C1 to the reference voltage level R1 at each end time T3. At each end time T3, the output Vout of the bias voltage supply 50 may change from a corresponding control section to a corresponding reference section. The control section may be an interval between the start time T2 and the end time T3 in each of the periods (cycles).

The start time T2 may occur (be positioned) to be delayed by an offset time interval (offset) from the power rise time TO in each of the periods (cycles). The control section may start later than the high-level section by the offset time interval (offset). At the power rise time TO, the output Vout of the bias voltage supply 50 may be a reference section. For example, each power rise time TO may occur during a corresponding reference section of the output Vout of the bias voltage supply 50. The offset time interval (offset) may be provided (predetermined) to be shorter than the length (interval) between the power rise time TO and the power fall time T1 in each of the periods (cycles). The offset time interval (offset) may be provided to be shorter than the length of the high-level section. Accordingly, the start time T2 may occur between the power rise time TO and the power fall time T1. The offset time interval (offset) may be equal to or shorter than ½ of the length of the high-level section. The offset time interval (offset) may be equal to or shorter than 10% of the length of the period of the output Fout of the source power supply 40. Alternatively, the offset time interval (offset) may be equal to or shorter than 5% of the length of the period T of the output Fout of the source power supply 40.

The length of the offset time interval (offset) may exceed 0 seconds such that there is an interval between the power rise time T0 and the start time T2. In contrast to the embodiment, when the length of the offset time interval (offset) is 0, there is no interval between the power rise time TO and the start time T2.

The end time T3 may be positioned to be delayed from the power fall time T1 by a margin time interval (mar). The control section may end later than the high-level section by the margin time interval (mar). The end time T3 may be positioned at a time in the low-level section. Accordingly, before the power rises from the low power level L1 to the high power level H1 at the power rise time T0 of the next period (cycle) of the output Fout of the source power supply 40, the output Vout of the bias voltage supply 50 may be changed, at the end time T3, from the control voltage level C1 to the reference voltage level R1. For example, during the reference section of the output Vout of the bias voltage supply 50, the power level of the output Fout of the source power supply 40 may rise to the high power level Hl at the power rise time T0.

The margin time interval (mar) may be provided to be shorter than the length (interval) between the power rise time T0 and the power fall time T1. The margin time interval (mar) may be provided to be shorter than the length of the high-level section. The margin time interval (mar) may be equal to or shorter than ½ of the length of the high-level section. The margin time interval (mar) may be longer than 0% of the length of one period of the output Fout of the source power supply 40 and be equal to or shorter than 10% of the length of one period of the output Fout of the source power supply 40.

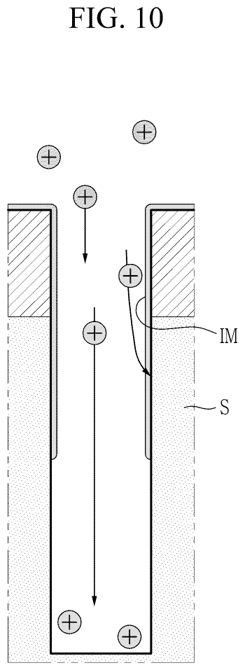

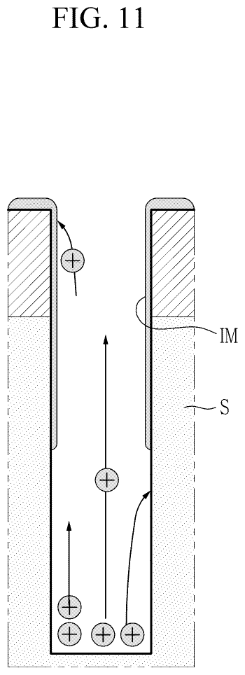

FIGS. 9 to 11 are views illustrating ion migration states in the course of the process of processing the substrate S. FIG. 9 is a view illustrating an ion migration state in the section between the start time T2 and the power fall time T1 shown in FIG. 8. FIG. 10 is a view illustrating an ion migration state in the section between the power fall time T1 and the end time T3 shown in FIG. 8. FIG. 11 is a view illustrating an ion migration state in the section between the end time T3 and the power rise time T0 of the next period shown in FIG. 8.

The ion migration states in the process of processing the substrate S will be described with reference to FIGS. 9 to 11.

Referring to FIG. 9, in the section between the start time T2 and the power fall time T1, the source power supply 40 provides power for exciting the plasma PL. Accordingly, the plasma PL may be excited inside the chamber 10. Further, the bias voltage supply 50 applies a voltage for controlling the state of the plasma PL to the support member 20. Accordingly, ions may migrate toward the substrate S positioned on the support member 20 and perform a process. As an example, the ions may perform an etching process on the substrate S.

Referring to FIG. 10, in the section between the power fall time T1 and the end time T3, the power supply of the source power supply 40 may be interrupted. Accordingly, the density of the plasma PL may decrease inside the chamber 10. Because the bias voltage supply 50 applies the voltage for controlling the state of the plasma PL to the support member 20, the ions may migrate toward and accumulate on the substrate S positioned on the support member 20. As an example, the ions may migrate to a trench formed in the substrate S through an etching process and accumulate in the inner space of the trench. Also, the ions may be attached to the inner walls of the trench, thereby forming an ionic membrane IM. The ionic membrane IM may be mainly formed in the upper portion of the trench.

Referring to FIG. 11, in the section between the end time T3 and the power rise time T0 of the next period, the power supply of the source power supply 40 may be maintained in the interrupted state. Further, the voltage application by the bias voltage supply 50 may be interrupted. Accordingly, the ions accumulated on the substrate S may migrate upwardly. As an example, the ions accumulated in the inner space of the trench may migrate upwardly. Also, by the ions, the thickness of the ionic membrane IM attached to the inner walls of the trench may increase. The ionic membrane IM may be mainly formed in the upper portion of the trench.

Thereafter, when the power rise time T0 of the next period occurs, the source power supply 40 applies the power for exciting the plasma PL. Accordingly, the plasma PL may be excited inside the chamber 10, and the substrate S is processed by the plasma PL. At this time, an ionic membrane IM formed on the substrate S may serve as a protective layer for the substrate S. Accordingly, the ionic membrane IM may prevent the upper region of the trench from being excessively etched such that the ionic membrane IM improves the uniformity of the critical dimension of the trench in the depth direction.

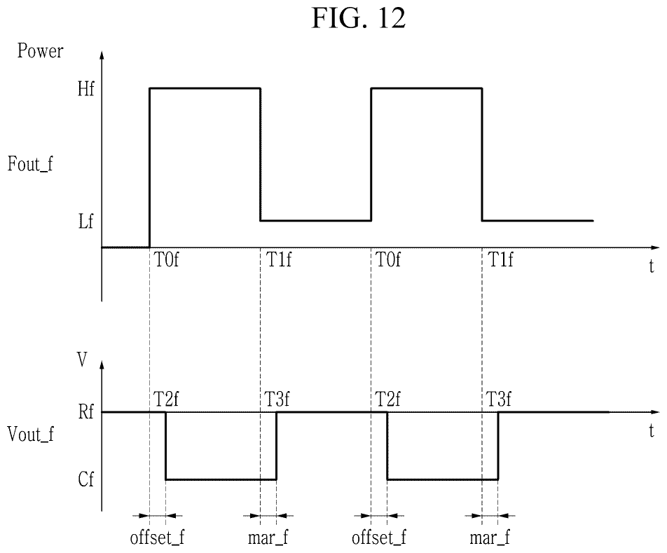

FIG. 12 is a view illustrating the state where an output Fout_f of the source power supply 40 and an output Vout_f of the bias voltage supply 50 change in sync with each other according to another exemplary embodiment.

The output Fout_f of the source power supply 40 may be a partial section of the output of the source power supply 40 described with reference to FIG. 3. The output Vout_f of the bias voltage supply 50 may be a partial section of one of the outputs of the bias voltage supply 50 described with reference to FIGS. 5 to 7.

Referring to FIG. 12, in each of the periods (cycles) of the waveform of the power level, the power level of the output Fout_f of the source power supply 40 may rise from a corresponding low-level section to a high power level Hf at a corresponding power rise time T0f, thereby changing to a corresponding high-level section. For example, in a first period after the source power supply 40 starts to supply power, at a power rise time T0f, the output Fout_f of the source power supply 40 may change from 0 W to a high-level section. Similarly, in a second period after the first period, at a power rise time T0f, the output Fout_f of the source power supply 40 may change from a low-level section to a high-level section.

In each of the periods (cycles) of the waveform of the power level, the power level of the output Fout_f of the source power supply 40 may fall, at corresponding power fall time T1f, thereby changing to a corresponding low-level section. For example, at each power fall time T1f, the output Fout_f of the source power supply 40 may change from a corresponding high-level section to a corresponding low-level section. Accordingly, at each power fall time T1f, the power level of the output Fout_f of the source power supply 40 may fall from the high power level Hf to a low power level Lf. The low power level Lf may be higher than 0 W, and be equal to or lower than 150 W.

The high-level section may be an interval between the power rise time T0f and the power fall time T1f in each of the periods.

The voltage level of the output Vout_f of the bias voltage supply 50 may fall from a reference voltage level Rf to a control voltage level Cf at each start time T2f. At each start time T2f, the output Vout_f of the bias voltage supply 50 may change from a corresponding reference section to a corresponding control section. The voltage level of the output Vout_f of the bias voltage supply 50 may rise from the control voltage level Cf to the reference voltage level Rf at each end time T3f. At each end time T3f, the output Vout_f of the bias voltage supply 50 may change from a corresponding control section to a corresponding reference section. The control section may be an interval between the start time T2f and the end time T3f in each of the periods.

The start time T2f may be positioned to be delayed by an offset time interval (offset_f) from the power rise time T0f in each of the periods. The control section may start later than the high-level section by the offset time interval (offset_f). At each power rise time T0f, the output Vout_f of the bias voltage supply 50 may be a reference section. For example, each power rise time T0f may occur during a corresponding reference section of the output Vout_f of the bias voltage supply 50. The offset time interval (offset_f) may be provided (predetermined) to be shorter than the length between the power rise time T0f and the power fall time T1f. The offset time interval (offset_f) may be provided to be shorter than the length of the high-level section. Accordingly, the start time T2f may be positioned between the power rise time T0f and the power fall time T1f. The offset time interval (offset_f) may be equal to or shorter than ½ of the length of the high-level section. The offset time interval (offset_f) may be equal to or shorter than 10% of the length of the period of the output Fout_f of the source power supply 40. Alternatively, the offset time interval (offset_f) may be equal to or shorter than 5% of the length of the period of the output Fout_f of the source power supply 40.

The length of the offset time interval (offset_f) may exceed 0 seconds such that there is an interval between the power rise time T0f and the start time T2f. In contrast to this embodiment, when the length of the offset time interval (offset) is 0, there is no interval between the power rise time T0f and the start time T2f.

The end time T3f may be positioned to be delayed from the power fall time T1f by a margin time interval (mar_f). The control section may end later than the high-level section by the margin time interval (mar_f). The end time T3f may be positioned at a time in the low-level section. For example, before the output Fout_f of the source power supply 40 rises to the high power level Hf at the power rise time T0f of the next period (cycle), the output Vout_f of the bias voltage supply 50 may be changed, at the end time T3f, from the control voltage level Cf to the reference voltage level Rf. For example, during the reference section of the output Vout_f of the bias voltage supply 50, the power level of the output Fout_f of the source power supply 40 may rise to the high power level Hf at the power rise time T0f.

The margin time interval (mar_f) may be provided to be shorter than the length between the power rise time T0f and the power fall time T1f. The margin time interval (mar_f) may be provided to be shorter than the length of the high-level section. The margin time interval (mar_f) may be equal to or shorter than ½ of the length of the high-level section. The margin time interval (mar_f) may be longer than 0% of the length of the period of the output Fout_f of the source power supply 40 and be equal to or shorter than 10% of the length of the period of the output Fout of the source power supply 40 (e.g., may be 0.5%, 1%, 2%, 5% or up to 10%).

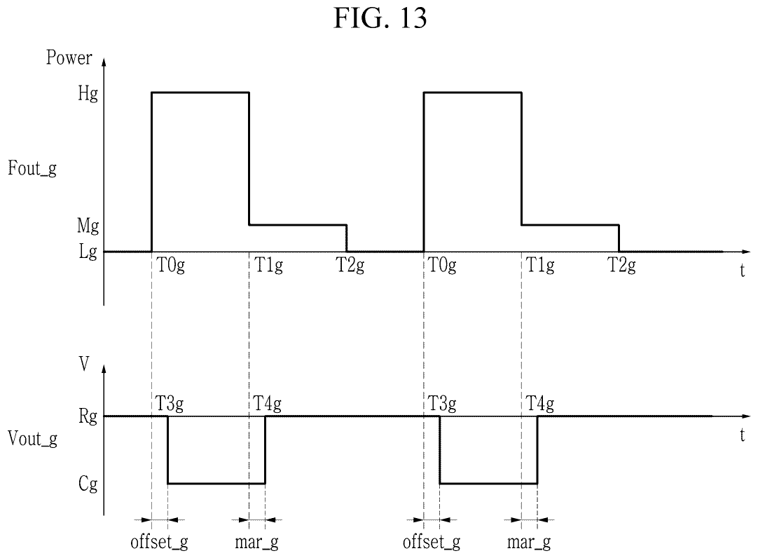

FIG. 13 is a view illustrating the state where an output Fout_g of the source power supply 40 and an output Vout_g of the bias voltage supply 50 change in sync with each other according to a further exemplary embodiment.

The output Fout_g of the source power supply 40 may be a partial section of the output of the source power supply 40 described with reference to FIG. 4. The output Vout_g of the bias voltage supply 50 may be a partial section of one of the outputs of the bias voltage supply 50 described with reference to FIGS. 5 to 7.

Referring to FIG. 13, in each of the periods (cycles) of the waveform of the power level, the power level of the output Fout_g of the source power supply 40 may rise at corresponding power rise time T0g. For example, in a first period after the source power supply 40 starts to supply power, at a power rise time T0g, the output Fout_g of the source power supply 40 may change from 0 W to a high-level section, or may change from a low-level section to the high-level section. In a second period after the first period, at a power rise time T0g, the output Fout_g of the source power supply 40 may change from a low-level section to a high-level section in a repetitive manner.

In each of the periods (cycles), the power level of the output Fout_g of the source power supply 40 may fall, at a corresponding first power fall time T1g, thereby changing to a corresponding middle-level section. For example, at each first power fall time T1g, the output Fout_g of the source power supply 40 may change from a corresponding high-level section to a corresponding middle-level section. Accordingly, at each first power fall time T1g, the power level of the output Fout_g of the source power supply 40 may fall from a high power level Hg to a middle power level Mg. The middle power level Mg may be higher than 0 W, and be equal to or lower than 150 W. The high-level section may be an interval between the power rise time T0g and the first power fall time T1g in each of the periods (cycles).

In each of the periods (cycles) of the waveform of the power level, the power level of the output Fout_g of the source power supply 40 may fall at a corresponding second power fall time T2g, thereby changing to a corresponding low-level section. For example, at each second power fall time T2g, the output Fout_g of the source power supply 40 may change from a corresponding middle-level section to a corresponding low-level section. Accordingly, the power level of the output Fout_g of the source power supply 40 may fall from the middle power level Mg to a low power level Lg at the second power fall time T2g. The middle-level section may be an interval between the first power fall time T1g and the second power fall time T2g in each of the periods (cycles).

The voltage level of the output Vout_g of the bias voltage supply 50 may fall from a reference voltage level Rg to a control voltage level Cg at each start time T3g. At each start time T3g, the output Vout_g of the bias voltage supply 50 may change from a corresponding reference section to a corresponding control section. The voltage level of the output Vout_g of the bias voltage supply 50 may rise from the control voltage level Cg to the reference voltage level Rg at each time T4g. For example, at each end time T4g, the output Vout_g of the bias voltage supply 50 may change from a corresponding control section to a corresponding reference section. The control section may be an interval between the start time T3g and the end time T4g in each of the periods.

The start time T3g may be positioned to be delayed by an offset time interval (offset_g) from the power rise time T0g. The control section may start later than the high-level section by the offset time interval (offset_g). The power rise time T0g may occur during the reference section of the output Vout_g of the bias voltage supply 50. The offset time interval (offset_g) may be provided to be shorter than the length between the power rise time T0g and the first power fall time T1g in each of the cycles. The offset time interval (offset_g) may be shorter than the length of the high-level section. Accordingly, the start time T3g may occur (is positioned) between the power rise time T0g and the first power fall time T1g. The offset time interval (offset_g) may be equal to or shorter than 10% of the length of the period of the output Fout_g of the source power supply 40. Alternatively, the offset time interval (offset_g) may be equal to or shorter than 5% of the length of the period of the output Fout_g of the source power supply 40.

The length of the offset time interval (offset_g) may exceed 0 seconds such that there is an interval between the power rise time T0g and the start time T3g. In contrast to this embodiment, when the length of the offset time interval (offset) is 0, there is no interval between the power rise time T0g and the start time T3g. The end time T4g may be positioned to be delayed from the first power fall time T1g by a margin time interval (mar_g). The control section may end later than the high-level section by the margin time interval (mar_g). The end time T4g may occur during the middle-level section.

Accordingly, during the reference section of the output Vout_g of the bias voltage supply 50, the output Fout_g of the source power supply 40 may change from the middle-level section to the low-level section, thereby falling from the middle power level Mg to the low power level Lg. Each second power fall time T2g occurs after a corresponding end time T4g and occurs before a corresponding start time T3g of the next period (cycle) of the output Vout_g of the bias voltage supply 50.

During the reference section of the output Vout_g of the bias voltage supply 50, the power level of the output Fout_g of the source power supply 40 may rise at each power rise time T0g.

The margin time interval (mar_g) may be provided to be shorter than the length between the power rise time T0g and the first power fall time T1g. The margin time interval (mar_g) may be provided to be shorter than the length of the high-level section. The margin time interval (mar_g) may be longer than 0% of the length of the period of the output Fout_g of the source power supply 40 and be equal to or shorter than 10% of the period of the output Fout_g of the source power supply 40.

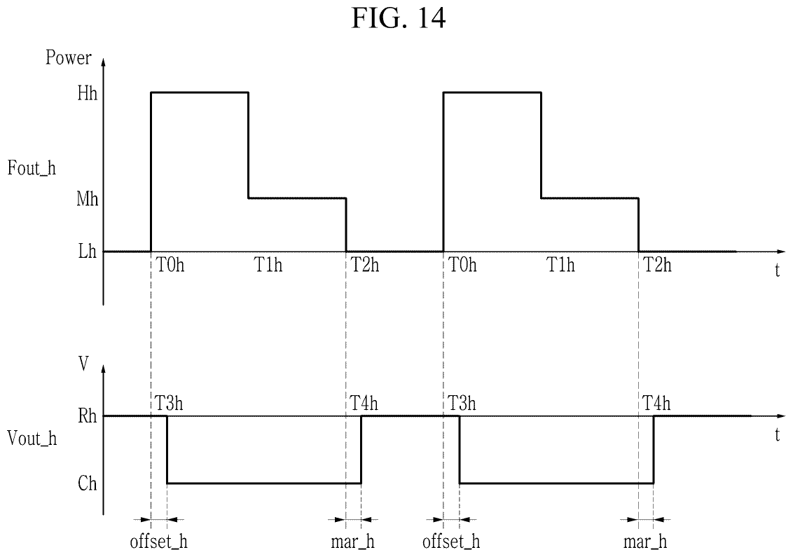

FIG. 14 is a view illustrating the state where an output Fout_h of the source power supply 40 and an output Vout_h of the bias voltage supply 50 change in sync with each other according to a still further exemplary embodiment.

The output Fout_h of the source power supply 40 may be a partial section of the output of the source power supply 40 described with reference to FIG. 4. The output Vout_h of the bias voltage supply 50 may be a partial section of one of the outputs of the bias voltage supply 50 described with reference to FIGS. 5 to 7.

Referring to FIG. 14, in each of the cycles, the power level of the output Fout_h of the source power supply 40 may rise at a corresponding power rise time T0h. For example, in a first period after the source power supply 40 starts to supply power, at a power rise time T0h, the output Fout_h of the source power supply 40 may change from 0 W to a high-level section, or may change from a low-level section to the high-level section.

in a second period after the first period, at a power rise time T0h, the output Fout_h of the source power supply 40 may change from a low-level section to a high-level section in a repetitive manner. The power level of the output Fout_h of the source power supply 40 may rise from a low power level Lh to a high power level Hh at each power rise time T0h.

In each of the periods (cycles) of the waveform of the power level, the power level of the output Fout_h of the source power supply 40 may fall, at a corresponding first power fall time T1h, thereby changing to a corresponding middle-level section. For example, at each first power fall time T1h, the output Fout_h of the source power supply 40 may change from a corresponding high-level section to a corresponding middle-level section. Accordingly, at each first power fall time T1h, the power level of the output Fout_h of the source power supply 40 may fall from the high power level Hh to a middle power level Mh. The middle power level Mh may be lower than the high power level Hh and exceed 150 W. The high-level section may be an interval between the power rise time T0h and the first power fall time T1h.

The power level of the output Fout_h of the source power supply 40 may fall at a second power fall time T2h, thereby changing to a corresponding low-level section in each of the periods (cycles) of the waveform of the power level in a repetitive manner. For example, at each second power fall time T2h, the output Fout_h of the source power supply 40 may change from a corresponding middle-level section to a corresponding low-level section. Accordingly, the power level of the output Fout_h of the source power supply 40 may fall from the middle power level Mh to the low power level Lh at each second power fall time T2h. The middle-level section may be an interval between the first power fall time T1h and the second power fall time T2h in each of the periods.

The voltage level of the output Vout_h of the bias voltage supply 50 may fall from a reference voltage level Rh to a control voltage level Ch at each start time T3h. At each start time T3h, the output Vout_h of the bias voltage supply 50 may change from a corresponding reference section to a corresponding section. The voltage level of the output Vout_h of the bias voltage supply 50 may rise from the control voltage level Ch to the reference voltage level Rh at an end time T4h. For example, at each end time T4h, the output Vout_h of the bias voltage supply 50 may change from a corresponding control section to a corresponding reference section. The control section may be an interval between the start time T3h and the end time T4h in each of the periods.

The start time T3h may be positioned to be delayed by an offset time interval (offset_h) from the power rise time T0h in each of the periods. The control section may start later than the high-level section by the offset time interval (offset_h). The power rise time T0h may occur during the reference section of the output Vout_h of the bias voltage supply 50. The offset time interval (offset_h) may be provided to be shorter than the length between the power rise time T0h and the second power fall time T2h. The offset time interval (offset_h) may be shorter than the sum of the lengths of the high-level section and the middle-level section in each of the periods. Accordingly, the start time T3h may be positioned between the power rise time T0h and the second power fall time T2h.

The offset time interval (offset_h) may be equal to or shorter than 10% of the length of the period of the output Fout_h of the source power supply 40. Alternatively, the offset time interval (offset_h) may be equal to or shorter than 5% of the length of the period of the output Fout_h of the source power supply 40.

The length of the offset time interval (offset_h) may exceed 0 seconds such that there is an interval between the power rise time T0h and the start time T3h. In contrast to this embodiment, when the length of the offset time interval (offset) is 0, there is no interval between the power rise time T0h and the start time T3h.

The end time T4h may be positioned to be delayed from the second power fall time T2h by a margin time interval (mar_h). The control section may end later than the middle-level section by the margin time interval (mar_h). The end time T4h may occur during the low-level section.

For example, before the output Fout_f of the source power supply 40 rises to the high power level Hh at the power rise time T0h of the next period (cycle), the output Vout_h of the bias voltage supply 50 may be changed, at the end time T3h, from the control voltage level Ch to the reference voltage level Rh.

For example, during the reference section of the output Vout_h of the bias voltage supply 50, the power level of the output Fout_h of the source power supply 40 may rise to the high power level Hh at the power rise time T0h.

The margin time interval (mar_h) may be provided to be shorter than the length between the power rise time T0h and the second power fall time T2h. The margin time interval (mar_h) may be provided to be shorter than the sum of the lengths of a high-level section and a middle-level section. The margin time interval (mar_h) may be longer than 0% of the length of the period of the output Fout_h of the source power supply 40 and be equal to or shorter than 10% of the length of the period of the output Fout_h of the source power supply 40.

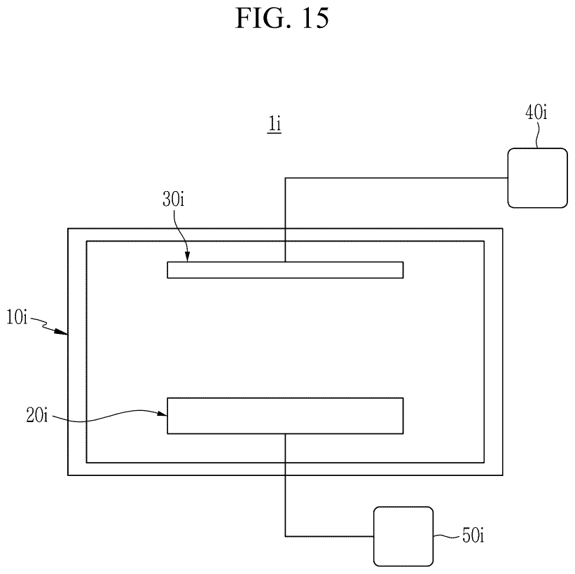

FIG. 15 is a view illustrating a substrate processing apparatus 1i according to another exemplary embodiment.

Referring to FIG. 15, the substrate processing apparatus li according to another exemplary embodiment may include a chamber 10i, a support member 20i, a plasma excitation member 30i, a source power supply 40i, and a bias voltage supply 50i.

The chamber 10i, the support member 20i, and the plasma excitation member 30i are identical or similar to those of the substrate processing apparatus 1 described with reference to FIG. 1, and thus, a redundant description thereof will not be made.

The source power supply 40i may be configured to provide power for excitation of plasma PL. The source power supply 40i may be connected to the plasma excitation member 30i. The source power supply 40i may include a high-frequency power source for generating high-frequency power. The source power supply 40i may include an RF power source. The source power supply 40i may output power for exciting the plasma PL in the same or similar manner as those in the exemplary embodiment described above with reference to FIGS. 2 to 4, and thus, a redundant description thereof will not be made.

The bias voltage supply 50i may be electrically connected to the support member 20i, and provides a voltage for bias. The bias voltage supply 50i may be electrically connected to the region which is made of the conductive material in the support member 20i. By the voltage which is supplied by the bias voltage supply 50i, in the region adjacent to the upper surface of the support member 20i, the state of a sheath, the state of concentration of the plasma PL on the substrate S, the state of incidence of ions to the substrate S, and the like may be adjusted.

The bias voltage supply 50i may output a voltage in the same or similar manner as those in the exemplary embodiment described above with reference to FIGS. 5 to 7, and thus, a redundant description thereof will not be made.

The substrate processing apparatus li may be utilized such that the output of the source power supply 40i and the output of the bias voltage supply 50i change in sync with each other in the manner which is identical or similar to those of the exemplary embodiment described above with reference to FIGS. 8 to 14, and thus, a redundant description thereof will not be made.

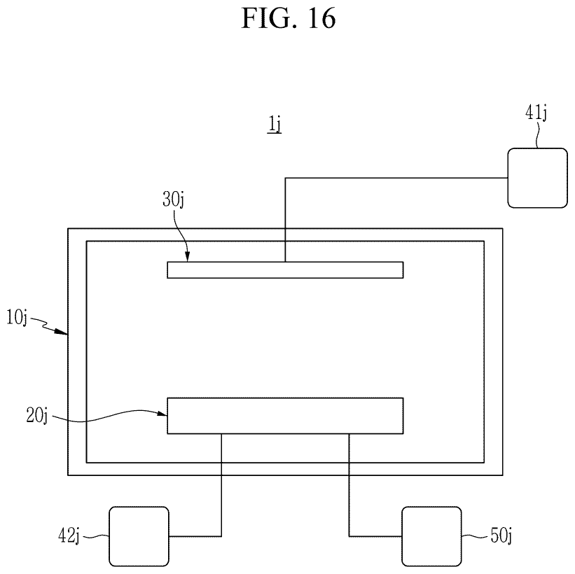

FIG. 16 is a view illustrating a substrate processing apparatus 1j according to a further exemplary embodiment.

Referring to FIG. 16, the substrate processing apparatus 1j according to the further exemplary embodiment may include a chamber 10j, a support member 20j, a plasma excitation member 30j, a source power supply (41j and 42j), and a bias voltage supply 50j.

The chamber 10j, the support member 20j, and the plasma excitation member 30j are identical or similar to those of the substrate processing apparatus 1 described with reference to FIG. 1, and thus, a redundant description thereof will not be made.

The source power supply (41j and 42j) may be configured to provide power for excitation of plasma PL. The source power supply (41j and 42j) may include a first source power supply 41j and a second source power supply 42j. The first source power supply 41j may be electrically connected to the plasma excitation member 30j. The first source power supply 41j may include a high-frequency power source for generating high-frequency power. The first source power supply 41j may include an RF power source.

The second source power supply 42j may be connected to the support member 20j. The second source power supply 42j may be electrically connected to the region made of the conductive material in the support member 20j. The second source power supply 42j may include another high-frequency power source for generating high-frequency power. The second source power supply 42j may include another RF power source. The first source power supply 41j and the second source power supply 42j may output power for exciting the plasma PL in the same or similar manner as those in the exemplary embodiment described above with reference to FIGS. 2 to 4. The first source power supply 41j and the second source power supply 42j may output power for exciting the plasma PL in sync with each other. Accordingly, the sum of the output power of the first source power supply 41j and the output power of the second source power supply 42j may be the power levels described with reference to FIGS. 2 to 4.

The bias voltage supply 50j may be electrically connected to the support member 20j, and provides a voltage for bias. The bias voltage supply 50j may be electrically connected to the region which is made of the conductive material in the support member 20j. By the voltage which is supplied by the bias voltage supply 50j, in the region adjacent to the upper surface of the support member 20j, the state of a sheath, the state of concentration of the plasma PL on the substrate S, the state of incidence of ions to the substrate S, and the like may be adjusted.

The bias voltage supply 50j may output a voltage in the same or similar manner as those in the exemplary embodiment described above with reference to FIGS. 5 to 7, and thus, a redundant description thereof will not be made.

The substrate processing apparatus 1j may be utilized such that, the output of the source power supply (41j and 42j) and the output of the bias voltage supply 50j change in sync with each other in the manner which is identical or similar to those of the exemplary embodiment described above with reference to FIGS. 8 to 14, and thus, a redundant description thereof will not be made.

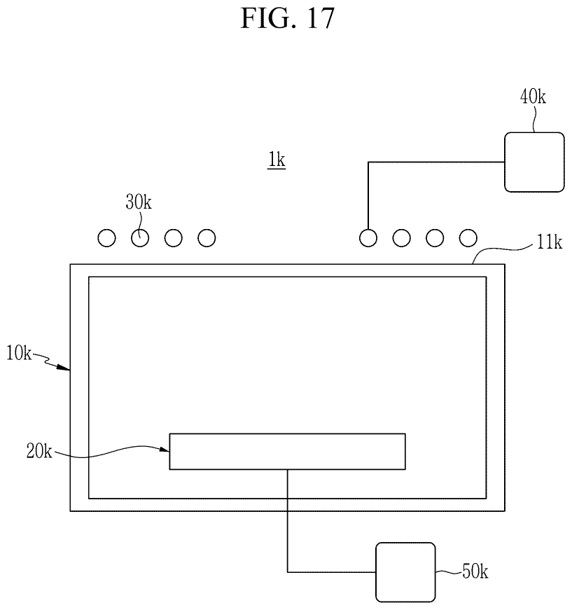

FIG. 17 is a view illustrating a substrate processing apparatus 1k according to a still further exemplary embodiment.

Referring to FIG. 17, the substrate processing apparatus 1k according to the still further exemplary embodiment may include a chamber 10k, a support member 20k, a plasma excitation member 30k, a source power supply 40k, and a bias voltage supply 50k.

The support member 20k may be identical or similar to that of the substrate processing apparatus 1 described with reference to FIG. 1, and thus, a redundant description thereof will not be made.

The chamber 10k may provide an inner process space where a process of processing the substrate S is performed. At least a portion of the top wall 11k of the chamber 10k may be made of a dielectric substance. The other configuration of the chamber 10k may be identical or similar to that of the chamber 10 of FIG. 1, and thus, a redundant description thereof will not be made.

The plasma excitation member 30k may be configured to provide energy for exciting the plasma PL inside of the chamber 10k. The plasma excitation member 30k may have an antenna structure. The plasma excitation member 30k may be disposed outside the chamber 10k. The plasma excitation member 30k may be disposed adjacent to the upper surface of the top wall 11k of the chamber 10k. The plasma excitation member 30k may be disposed to face the inner space of the chamber 10k with the top wall 11k of the chamber 10k interposed therebetween.

The source power supply 40k may be configured to provide power for excitation of the plasma PL. The source power supply 40k may be electrically connected to the plasma excitation member 30k. The source power supply 40k may include a high-frequency power source for generating high-frequency power. The source power supply 40k may include an RF power source. The plasma excitation member 30k may generate an electromagnetic wave by the power which is provided by the source power supply 40k. A gas introduced into the chamber 10k may be excited into plasma PL by the electromagnetic wave generated by the plasma excitation member 30k.

The source power supply 40k may output power for exciting the plasma PL in the same or similar manner as in the exemplary embodiment described above with reference to FIGS. 2 to 4, and thus, a redundant description thereof will not be made.

The bias voltage supply 50k may be electrically connected to the support member 20k, and provides a voltage for bias. The bias voltage supply 50k may be electrically connected to the region which is made of the conductive material in the support member 20k. By the voltage which is supplied by the bias voltage supply 50k, in the region adjacent to the upper surface of the support member 20k, the state of a sheath, the state of concentration of the plasma PL on the substrate S, the state of incidence of ions to the substrate S, and the like may be adjusted.

The bias voltage supply 50k may output a voltage in the same or similar manner as those in the exemplary embodiment described above with reference to FIGS. 5 to 7, and thus, a redundant description thereof will not be made.

The substrate processing apparatus 1k may be utilized such that, the form in which the output of the source power supply 40k and the output of the bias voltage supply 50k change in sync with each other in the matter which is identical or similar to those of the exemplary embodiment described above with reference to FIGS. 8 to 14, and thus, a redundant description thereof will not be made.

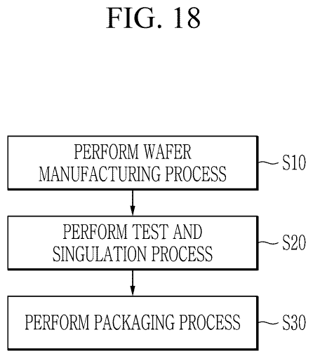

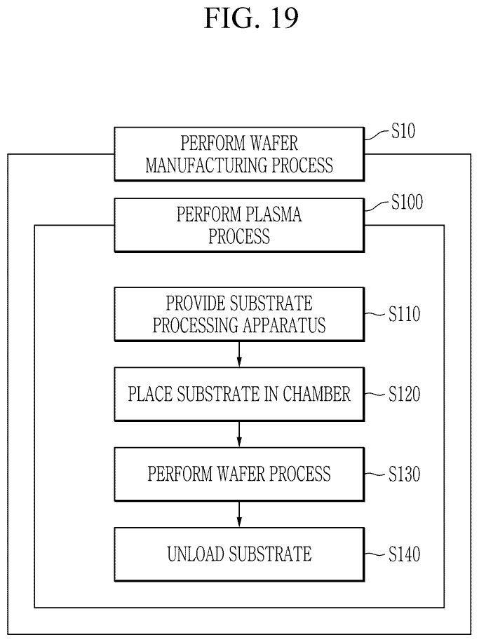

FIGS. 18 and 19 are flowcharts illustrating a method of manufacturing a semiconductor device according to an embodiment.

Referring to FIG. 18, an operation S10 of performing wafer manufacturing process may be performed, thereby providing a semiconductor wafer on which a plurality of semiconductor chips (devices) are formed. In the an operation S10, one or more processes may be performed. For example, an oxidation process, a photolithography process, a deposition process, an etching process, an ion process, and/or a cleaning process may be performed to form the semiconductor wafer having the individual chips.

Subsequently, an operation S20 of performing wafer test process may be performed, thereby classifying the chips (which are undiced (not singulated)). For example, the operation S20 may be an electrical die sorting (EDS) process, which may test electrical characteristics of the plurality of semiconductor chips.

In an operation S30, the semiconductor wafer may be singulated (divided) into a plurality of diced chips by, e.g., a sawing process. During the operation S30, one or more of the diced chips may be disposed on a package substrate, and the individual chips may be molded by e.g., a molding compound, thereby providing a semiconductor package device.

FIG. 19 illustrate a plasma process S100 as an example of processes performed in the operation S10. For example, the example may be an etching process.

Referring to FIG. 19 and FIGS. 1 to 17, in an operation S110, a substrate processing apparatus may be provided. For example, the plasma process is a way of processing a substrate (wafer) by using one of the substrate processing apparatuses discussed with reference to FIG. 1 and FIGS. 15 to 17.

In an operation S110, the substrate S may be positioned on the support member.

In an operation S130, the substrate may be etched by using plasma. During the etching, the plasma may be excited and controlled by the source power and the bias voltage as discussed above.

As an example, the etching process will be described with reference to FIGS. 8 to 11.

Referring to FIGS. 8 and 9, in the section between the start time T2 and the power fall time T1, the source power supply 40 provides power for exciting the plasma PL. Accordingly, the plasma PL may be excited inside the chamber 10. Further, the bias voltage supply 50 applies a voltage for controlling the state of the plasma PL to the support member 20. The ions may perform an etching process on the substrate S.

Referring to FIGS. 8 and 10, in the section between the power fall time T1 and the end time T3, the power supply of the source power supply 40 may be interrupted. Accordingly, the density of the plasma PL may decrease inside the chamber 10. The ionic membrane IM may be formed in the upper portion of the trench.

Referring to FIGS. 8 and 11, in the section between the end time T3 and the power rise time T0 of the next period, the power supply of the source power supply 40 may be maintained in the interrupted state. Further, the voltage application by the bias voltage supply 50 may be interrupted. The thickness of the ionic membrane IM attached to the inner walls of the trench may increase.

Thereafter, when the power rise time T0 of the next period occurs, the source power supply 40 applies the power for exciting the plasma PL. Accordingly, the plasma PL may be excited inside the chamber 10, and the substrate S is processed by the plasma PL. At this time, an ionic membrane IM formed on the substrate S may serve as a protective layer for the substrate S. Accordingly, the ionic membrane IM may prevent the upper region of the trench from being excessively etched such that the ionic membrane IM improves the uniformity of the critical dimension of the trench in the depth direction. After the etching process is completed, the substrate may be unloaded in an operation S140.

Though the etching process is described with reference to FIGS. 8 to 11, other embodiments (e.g., those described with reference to the other figures) may also be used in conjunction with the etching process. Additionally, features from the alternative embodiments described with reference to other drawings may replace a portion of features of the etching process described with reference to FIGS. 8 to 11. For example, other waveforms of power source and/or bias voltage may be applicable.

While this invention has been described in connection with what is presently considered to be practical exemplary embodiments, it is to be understood that the invention is not limited to the disclosed embodiments. On the contrary, it is intended to cover various modifications and equivalent arrangements included within the spirit and scope of the appended claims. For example, though the embodiments described above may be related to an etching process and a substrate processing apparatus for performing the etching process, the inventive concept may also be applied to various other processes like ashing, ion implantation, thin-film deposition, cleaning, etc. and related substrate processing apparatuses.

1. A substrate processing apparatus comprising:
a chamber;
a source power supply configured to generate a source power such that a power level of an output of the source power pulses, thereby exciting plasma in the chamber;
a support member disposed inside the chamber and configured to support a substrate; and
a bias voltage supply connected to the support member and configured to generate a bias voltage,
wherein:
the source power supply is configured such that the power level of the output of the source power supply falls at a power fall time, and
the bias voltage supply is configured such that a voltage level of an output of the bias voltage supply rises from a control voltage level to a reference voltage level at an end time, and the end time occurs later than the power fall time by a margin time interval.

2. The substrate processing apparatus of claim 1, wherein the source power supply is configured such that the power level of the output of the source power supply falls from a high power level to a low power level at the power fall time.

3. The substrate processing apparatus of claim 2, wherein the low power level is 0 W.

4. The substrate processing apparatus of claim 2, wherein the low power level is higher than 0 W and is equal to or lower than 150 W.

5. The substrate processing apparatus of claim 2, wherein the high power level is equal to or higher than 1000 W.

6. The substrate processing apparatus of claim 2, wherein:
the source power supply is configured such that the power level of the output of the source power supply rises from the low power level to the high power level at a power rise time, and
the bias voltage supply is configured such that the voltage level of the output of the bias voltage supply falls from the reference voltage level to the control voltage level at a start time, and the start time occurs later than the power rise time by an offset time interval.

7. The substrate processing apparatus of claim 6, wherein the offset time interval exceeds 0% of a length of a period of the output of the source power supply and is equal to or shorter than 10% of the length of the period of the output of the source power supply.

8. The substrate processing apparatus of claim 1, wherein the margin time interval exceeds 0% of a length of a period of the output of the source power supply and is equal to or shorter than 10% of the length of the period of the output of the source power supply.

9. The substrate processing apparatus of claim 1, wherein the source power supply is configured such that the power level of the output of the source power supply falls from a high power level to a middle power level at the power fall time.

10. The substrate processing apparatus of claim 9, wherein the middle power level is higher than 0 W and is equal to or lower than 150 W.

11. The substrate processing apparatus of claim 9, wherein:
the source power supply is configured such that the power level of the output of the source power supply rises from a low power level lower than the middle power level to the high power level at a power rise time, and
the bias voltage supply is configured such that the voltage level of the output of the bias voltage supply falls from the reference voltage level to the control voltage level at a start time, and the start time occurs later than the power rise time by an offset time interval.

12. A substrate processing apparatus comprising:
a chamber;
a source power supply configured to generate a source power and configured such that a power level of an output of the source power pulses, thereby exciting plasma in the chamber;
a support member that is disposed inside the chamber and is configured to support a substrate; and
a bias voltage supply that is connected to the support member and is configured to generate a bias voltage such that a voltage level of an output of the bias voltage supply pulses,
wherein:
the source power supply is configured such that the power level of the output of the source power supply falls at a power fall time,
the bias voltage supply is configured such that the voltage level of the output of the bias voltage supply is changed between a control section and a reference section, and at an end time, the voltage level of the output of the bias voltage supply changes from the control section to the reference section, and
the end time occurs later than the power fall time by a margin time interval.

13. The substrate processing apparatus of claim 12, wherein the source power supply is configured such that, at the power fall time, the power level of the output of the source power supply falls from a high power level which is equal to or higher than 1000 W to a predetermined power level which exceeds 0 W and is equal to or lower than 150 W.

14. The substrate processing apparatus of claim 12, wherein the source power supply is configured such that, at the power fall time, the power level of the output of the source power supply falls to 0 W from a high power level which is equal to or higher than 1000 W.

15. The substrate processing apparatus of claim 12, wherein:
the source power supply is configured to provide the power level of the output of the source power supply in a periodic waveform with a first period;
the bias voltage supply is configured to provide the voltage level of the output of the bias voltage supply in a periodic waveform with a second period; and
the first and second periods are the same as each other.

16. The substrate processing apparatus of claim 12, wherein:
the source power supply is configured such that the power level of the output of the source power supply rises at a power rise time, and
at a start time, the voltage level of the output of the bias voltage supply changes from the reference section to the control section, and
the start time occurs later than the power rise time by an offset time interval.

17. The substrate processing apparatus of claim 16, wherein the source power supply is configured such that the power level of the output of the source power supply to rises to a high power level equal to or higher than 1000 W at the power rise time.

18. The substrate processing apparatus of claim 16, wherein:
the source power supply is configured to provide the power level of the output of the source power supply in a periodic waveform with a predetermined period, and
the offset time interval exceeds 0% of a length of the predetermined period of the output of the source power supply and is equal to or shorter than 10% of the length of the predetermined period of the output of the source power supply.

19. A substrate processing apparatus comprising:
a chamber;
a source power supply configured to generate a source power and configured such that a power level of an output of the source power pulses, thereby exciting plasma in the chamber;
a support member that is disposed inside the chamber and is configured to support a substrate; and
a bias voltage supply that is connected to the support member and is configured to generate a bias voltage such that a voltage level of an output of the bias voltage pulses,
wherein:
the source power supply is configured such that the power level of the output of the source power supply:
rises to 1000 W or more at a power rise time, and
falls to 150 W or less at a power fall time,
the bias voltage supply is configured such that the voltage level of the output of the bias voltage supply, at an end time, is changed from a control section to a reference section, and
the end time occurs later than the power fall time by a margin time interval.

20. The substrate processing apparatus of claim 19, wherein the margin time interval is shorter than a length of a predetermined section in which the power level of the output of the source power supply is equal to or higher than 1000 W.

21-27. (canceled)
